(19) United States
(12) Patent Application Publication
(10) Pub. No.: US 2013/0241044 A1
(43) Pub. Date: Sep. 19, 2013

(54) SEMICONDUCTOR PACKAGE HAVING PROTECTIVE LAYER AND METHOD OF FORMING THE SAME

(71) Applicant: SAMSUNG ELECTRONICS CO., LTD., Suwon-si (KR)

(72) Inventors: Hyun-Ki KIM, Cheonan-si (KR); Jung-Do LEE, Uiwang-si (KR); Yang-Hoon AHN, Asan-si (KR); Sun-Hye LEE, Cheongju-si (KR); Dae-Young CHOI, Yeosu-si (KR)

(73) Assignee: SAMSUNG ELECTRONICS CO., LTD., Suwon-Si (KR)

(21) Appl. No.: 13/668,852

(22) Filed: Nov. 5, 2012

(30) Foreign Application Priority Data
Mar. 16, 2012 (KR) 10-2012-0027383

(51) Int. Cl. H01L 23/48; H01L 23/02

(52) U.S. Cl. 257/698; 257/678; 257/E23.011; 257/E23.18

(57) ABSTRACT

According to example embodiments, a semiconductor package includes a first semiconductor chip is on a first substrate, a protective layer directly on the first semiconductor chip, and an encapsulant covering an upper surface of the first substrate. The encapsulant may contact side surfaces of the first semiconductor chip and the protective layer.

### CROSS-REFERENCE TO RELATED APPLICATION

This application claims priority under 35 U.S.C. §119 to Korean Patent Application No. 10-2012-0027383 filed on Mar. 16, 2012, the disclosure of which is hereby incorporated by reference in its entirety.

### BACKGROUND

1. Field

Example embodiments of inventive concepts relate to a semiconductor package having a protective layer mounted on a flip-chip and a method of forming the same.

2. Description of Related Art

Various technologies have been studied to achieve the objectives of a light, thin, short, and a small semiconductor package.

### SUMMARY

Example embodiments of inventive concepts relate to a semiconductor package which may be relatively thin, impact-resistant, and effective for dissipating heat, and a method of forming the same.

However, technical objectives of example embodiments of inventive concepts are not limited to the above disclosure, and other objectives may become apparent to those of ordinary skill in the art based on the following description.

According to example embodiments of inventive concepts, a semiconductor package may include a first semiconductor chip on a first substrate, a protective layer directly on the first semiconductor chip, and an encapsulant covering an upper surface of the first substrate. The encapsulant may contact side surfaces of the first semiconductor chip and the protective layer. The first semiconductor chip may be mounted on the first substrate.

A second substrate may be on the protective layer and the encapsulant. A second semiconductor chip may be mounted on the second substrate. The second substrate may be mounted on the protective layer and the encapsulant. A through-electrode may be connected through the encapsulant to the first and second substrates. The protective layer may be in contact with the second substrate.

An upper surface of the encapsulant may be at a lower level than an upper surface of the first semiconductor chip.

An upper surface of the encapsulant may be at a higher level than the first semiconductor chip. The upper surfaces of the encapsulant and the protective layer may be formed at the same level.

A width of the protective layer may be greater than a width of the first semiconductor chip.

The protective layer may be in contact with an upper surface of the first semiconductor chip and the side surfaces of the first semiconductor chip.

The protective layer may include a thermal interface material (TIM).

According to example embodiments of inventive concepts, a semiconductor package may include a first semiconductor chip on a first substrate, an encapsulant covering an upper surface of the first substrate, the encapsulant contacting a side surface of the first semiconductor chip, a protective layer directly contacting an upper surface of the first semiconductor chip and an upper surface of the encapsulant. The protective layer may include a TIM. A width of the protective layer may be greater than a width of the first semiconductor chip.

A second substrate may be on the protective layer. A second semiconductor chip may be on the second substrate. A through-electrode may be connected through the protective layer and the encapsulant to the first and second substrates. The encapsulant may include a protrusion in contact with a side surface of the protective layer. Upper ends of the protrusion and the protective layer may be at the same level.

An upper surface of the encapsulant may be at a lower level than an upper end of the first semiconductor chip.

A thickness of the protective layer between the encapsulant and the second substrate may be greater than a thickness of the protective layer between the first semiconductor chip and the second substrate.

According to example embodiments of inventive concepts, a semiconductor package includes an encapsulant on a first substrate, a first semiconductor chip on the encapsulant, and a protective layer directly on the first semiconductor chip. The encapsulant may contact a sidewall of the first semiconductor chip. The protective layer may contact at least one of an upper surface of the encapsulant, the sidewall of the first semiconductor chip, and a sidewall of the encapsulant.

The protective layer may contact a first part of the sidewall of the first semiconductor chip. The encapsulant may contact a second part of the sidewall of the first semiconductor chip. The protective layer may extend between the encapsulant and the first part of the sidewall of the first semiconductor chip.

A width of the protective layer may be different than a width of the first semiconductor chip. A portion of the encapsulant may extend between the sidewall of the first semiconductor chip and the protective layer.

A second substrate may be on the protective layer. A second semiconductor chip may be on the second substrate.

The protective layer may include a first pattern containing a thermally-conductive adhesive, and a second pattern containing a different material than the first pattern.

### BRIEF DESCRIPTION OF THE DRAWINGS

The foregoing and other features and advantages of inventive concepts will be apparent from the more particular description of non-limiting embodiments of inventive concepts, as illustrated in the accompanying drawings in which like reference characters refer to the same parts throughout the different views. The drawings are not necessarily to scale, emphasis placed upon illustrating the principles of inventive concepts. In the drawings:

FIG. 1 is a cross-sectional view for describing a semiconductor package and a method of forming the same according to example embodiments of inventive concepts;

FIGS. 2 to 16 are enlarged views illustrating a portion of the semiconductor package shown in FIG. 1 in detail;

FIGS. 17 to 23A are enlarged views illustrating some components of the semiconductor package shown in FIG. 1 in detail;

FIG. 23B is a plan view of FIG. 23A;

FIGS. 24 to 31 are cross-sectional views for describing a semiconductor package and a method of forming the same according to example embodiments of inventive concepts;

FIGS. 32 to 35 are enlarged views illustrating a portion of the semiconductor package shown in FIG. 31 in detail;

FIG. 36 is a cross-sectional view for describing a semiconductor package and a method of forming the same according to example embodiments of inventive concepts;

FIGS. 37 to 39 are enlarged views illustrating a portion of the semiconductor package shown in FIG. 36 in detail;

FIGS. 40 to 43 are cross-sectional views for describing a semiconductor package and a method of forming the same according to example embodiments of inventive concepts;

FIGS. 44 and 45 are system block diagrams for describing electronic devices according to example embodiments of inventive concepts; and

FIGS. 46 and 47 illustrate a portion of semiconductor packages according to example embodiments.

### DETAILED DESCRIPTION OF THE EMBODIMENTS

Example embodiments will now be described more fully with reference to the accompanying drawings in which some embodiments are shown. Example embodiments of inventive concepts may, however, be embodied in different forms and should not be construed as limited to the embodiments set forth herein. Rather, these embodiments are provided so that this disclosure is thorough and complete and will fully convey inventive concepts to those skilled in the art. In the drawings, the sizes and relative sizes of layers and regions may be exaggerated for clarity. Like reference numerals in the drawings denote like elements, and thus their description may be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiments of inventive concepts.

Spatially relative terms, such as “beneath,” “below,” “lower,” “above,” “upper” and the like, may be used herein for ease of description to describe one element's or feature's relationship to another elements or features as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented rotated 90 degrees or at other orientations and the spatially relative descriptors used herein interpreted accordingly.

The terminology used herein is for the purpose of describing particular embodiments only and is not intended to be limiting of example embodiments of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of inventive concepts are described herein with reference to cross-sectional illustrations that are schematic illustrations of idealized embodiments and intermediate structures. As such, variations from the shapes of the illustrations as a result, for example, of manufacturing techniques and/or tolerances, are to be expected. Thus, example embodiments of inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments of inventive concepts.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

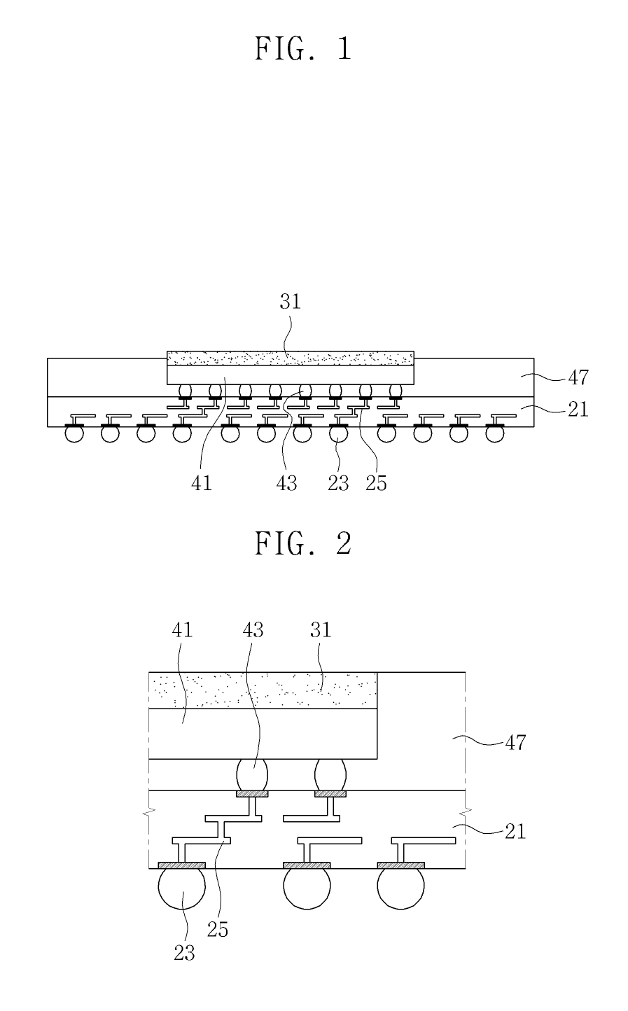

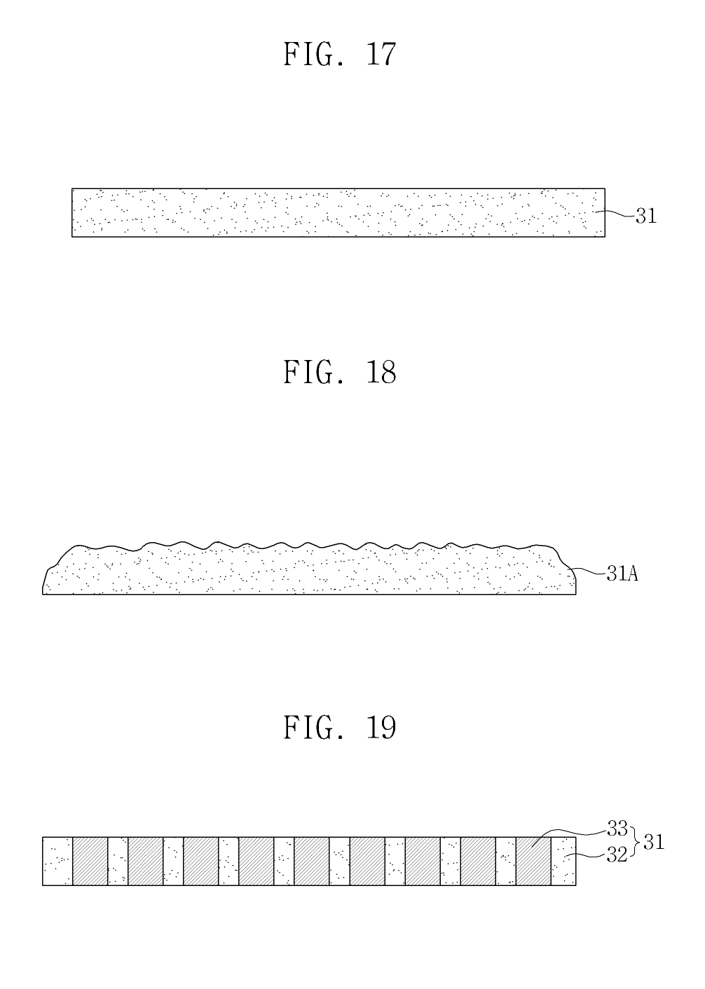

FIG. 1 is a cross-sectional view for describing a semiconductor package according to example embodiments of inventive concepts, FIGS. 2 to 16 are enlarged views showing a portion of the semiconductor package shown in FIG. 1 in detail, FIGS. 17 to 23A are enlarged views showing some components of the semiconductor package shown in FIG. 1, and FIG. 23B is a plan view of FIG. 23A.

Referring to FIG. 1, a first semiconductor chip 41 and a protective layer 31 may be mounted on a first substrate 21. Also, a first encapsulant 47 may be formed on the first substrate 21. The first encapsulant 47 may be in contact with side surfaces of the first semiconductor chip 41 and the protective layer 31. The protective layer 31 may include a thermal interface material (TIM).

The first substrate 21 may be a rigid printed circuit board (PCB), a flexible PCB, or a rigid-flexible PCB. In addition, the first substrate 21 may be a multi-layer PCB. The first substrate 21 may include a plurality of internal wirings 25. External terminals 23 may be formed in one surface of the first substrate 21. The external terminals 23 may include a solder ball, a conductive bump, a pin grid array, a lead grid array, a conductive tab, or a combination thereof. The external terminals 23 may be connected to the internal wirings 25. However example embodiments of inventive concepts are not limited thereto and the external terminals 23 may be omitted.

The first semiconductor chip 41 may be a logic chip such as a microprocessor or a controller. Internal terminals 43 may be formed between the first substrate 21 and the first semiconductor chip 41. The internal terminals 43 may include a solder ball, a conductive bump, a conductive tab, or a combination thereof. The first semiconductor chip 41 may be electrically connected to the external terminals 23 via the internal terminals 43 and the internal wirings 25. The first semiconductor chip 41, the internal terminals 43, and the first substrate 21 may be configured to form a flip-chip package.

The first encapsulant 47 may include a thermosetting resin such as a molding compound. The first encapsulant 47 may cover one surface of the first substrate 21. The first encapsulant 47 may fill a space between the first semiconductor chip 41 and the first substrate 21. The internal terminals 43 may be connected to the first semiconductor chip 41 and the internal wirings 25 through the first encapsulant 47. A side surface of the first encapsulant 47 may be vertically aligned with a side surface of the first substrate 21.

Referring to FIG. 2, an upper surface of the first encapsulant 47 may be formed at a higher level than the first semiconductor chip 41. For example, upper surfaces of the first encapsulant 47 and the protective layer 31 may be formed at substantially the same level. The protective layer 31 may have the same width as the first semiconductor chip 41. The protective layer 31 may be directly in contact with the upper surface of the first semiconductor chip 41. The side surface of the protective layer 31 may be vertically aligned with the side surface of the first semiconductor chip 41. The first encapsulant 47 may fully cover the side surfaces of the first semiconductor chip 41 and the protective layer 31.

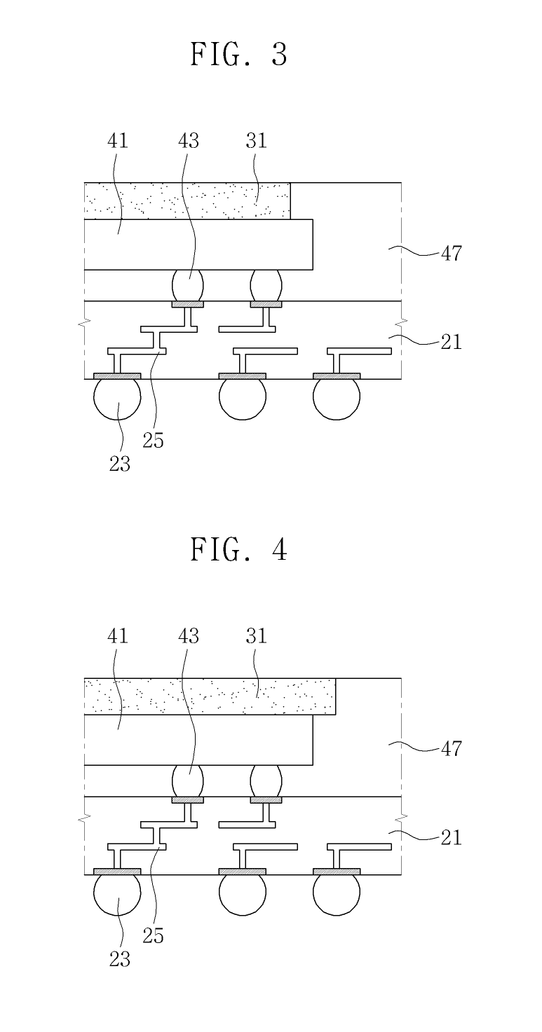

Referring to FIG. 3, the protective layer 31 may have a smaller width than the first semiconductor chip 41. The upper surfaces of the first encapsulant 47 and the protective layer 31 may be formed at substantially the same level. The first encapsulant 47 may partially cover the upper surface of the first semiconductor chip 41 and be in contact with the side surface of the protective layer 31.

Referring to FIG. 4, the protective layer 31 may have a greater width than the first semiconductor chip 41. The upper surfaces of the first encapsulant 47 and the protective layer 31 may be formed at substantially the same level. The first encapsulant 47 may be in contact with the side surface and bottom of the protective layer 31.

Referring to FIG. 5, the protective layer 31 may have a greater width than the first semiconductor chip 41. The protective layer 31 may partially cover the side surface of the first semiconductor chip 41. The protective layer 31 may be interposed between the first semiconductor chip 41 and the first encapsulant 47. The upper surfaces of the first encapsulant 47 and the protective layer 31 may be formed at substantially the same level.

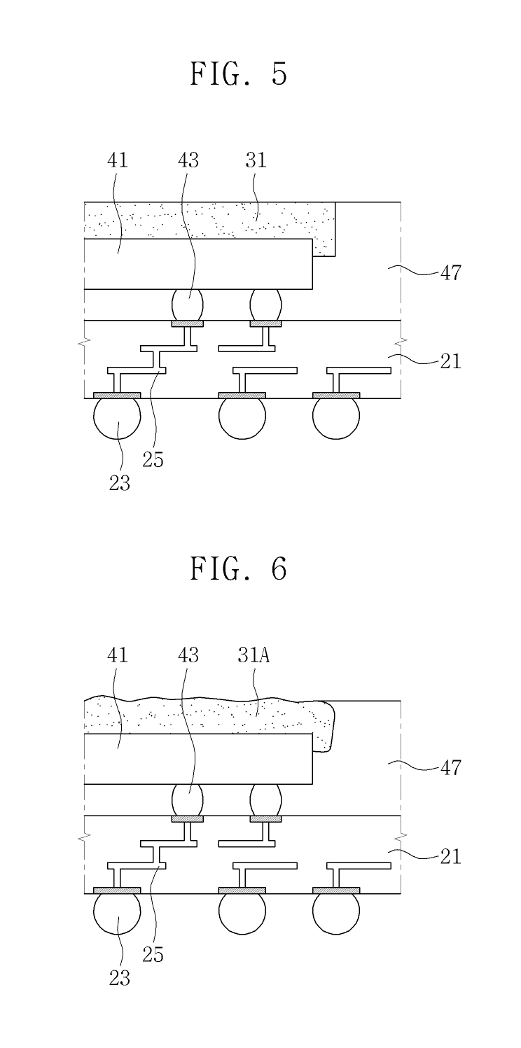

Referring to FIG. 6, the surface of the protective layer 31A may be uneven. The protective layer 31A may fully cover the upper surface of the first semiconductor chip 41 and partially cover the side surface of the first semiconductor chip 41. The protective layer 31A may be interposed between the first semiconductor chip 41 and the first encapsulant 47. The upper surfaces of the first encapsulant 47 and the protective layer 31A may be formed at substantially the same level.

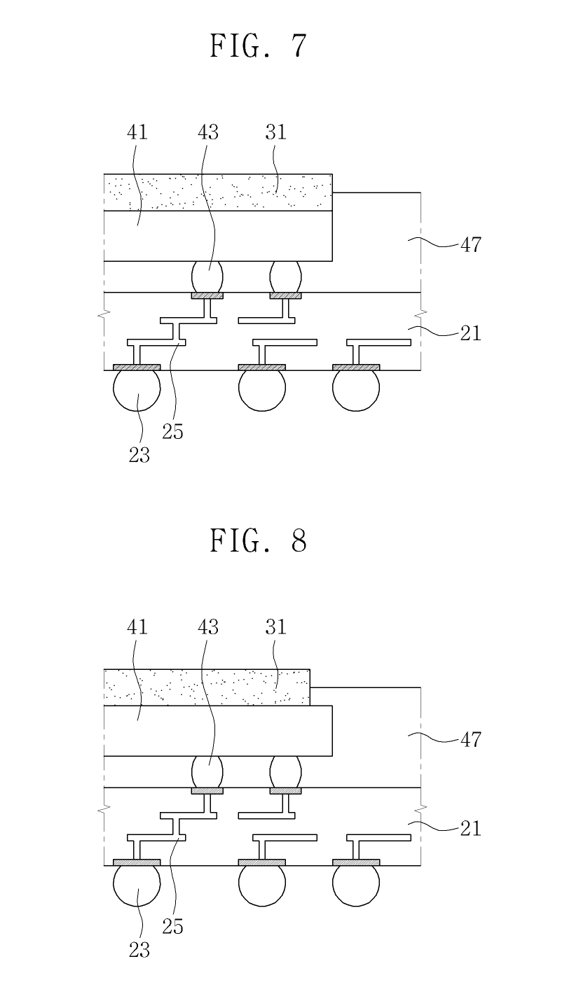

Referring to FIG. 7, the upper surface of the first encapsulant 47 may be located at a higher level than the first semiconductor chip 41 and at a lower level than the upper end of the protective layer 31. The protective layer 31 may have the same width as the first semiconductor chip 41. The first encapsulant 47 may fully cover the side surface of the first semiconductor chip 41 and partially cover the side surfaces of the protective layer 31. For example, the upper end of the protective layer 31 may protrude at a level higher than the first encapsulant 47.

Referring to FIG. 8, the protective layer 31 may have a smaller width than the first semiconductor chip 41. The first encapsulant 47 may partially cover the upper surface of the first semiconductor chip 41 and be in contact with the side surface of the protective layer 31. The upper surface of the first encapsulant 47 may be located at a higher level than the first semiconductor chip 41 and at a lower level than the upper end of the protective layer 31.

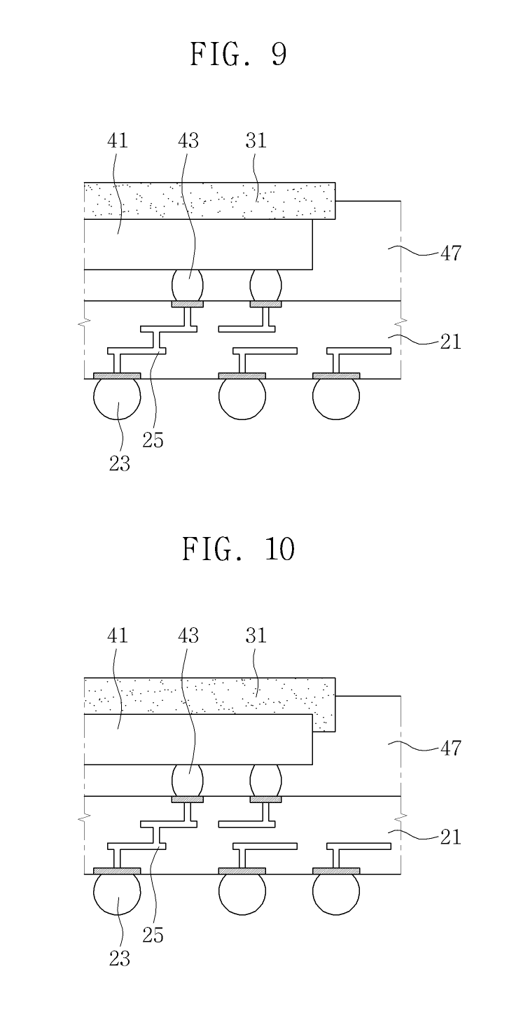

Referring to FIG. 9, the protective layer 31 may have a greater width than the first semiconductor chip 41. The upper surface of the first encapsulant 47 may be located at a higher level than the first semiconductor chip 41 and at a lower level than the upper end of the protective layer 31. The first encapsulant 47 may be in contact with the bottom of the protective layer 31 and partially in contact with the side surface of the protective layer 31.

Referring to FIG. 10, the protective layer 31 may have a greater width than the first semiconductor chip 41. The protective layer 31 may partially cover the side surface of the first semiconductor chip 41. The upper surface of the first encapsulant 47 may be located at a higher level than the first semiconductor chip 41 and at a lower level than the upper end of the protective layer 31. The protective layer 31 may be interposed between the first semiconductor chip 41 and the first encapsulant 47.

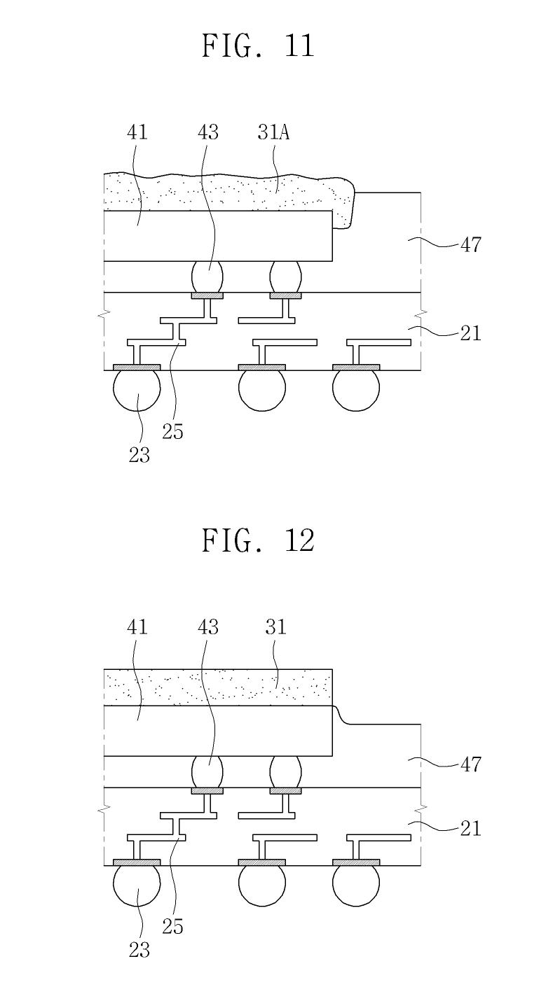

Referring to FIG. 11, the surface of the protective layer 31A may be uneven. The protective layer 31A may fully cover the upper surface of the first semiconductor chip 41 and partially cover the side surface of the first semiconductor chip 41. The upper surface of the first encapsulant 47 may be located at a higher level than the first semiconductor chip 41 and at a lower level than the upper end of the protective layer 31A. The protective layer 31A may be interposed between the first semiconductor chip 41 and the first encapsulant 47.

Referring to FIG. 12, the first encapsulant 47 may be located at a lower level than the protective layer 31. For example, the upper surface of the first encapsulant 47 may be located at the same level as or a lower level than the upper end of the first semiconductor chip 41. The protective layer 31 may have the same width as the first semiconductor chip 41. The first encapsulant 47 may cover the side surface of the first semiconductor chip 41.

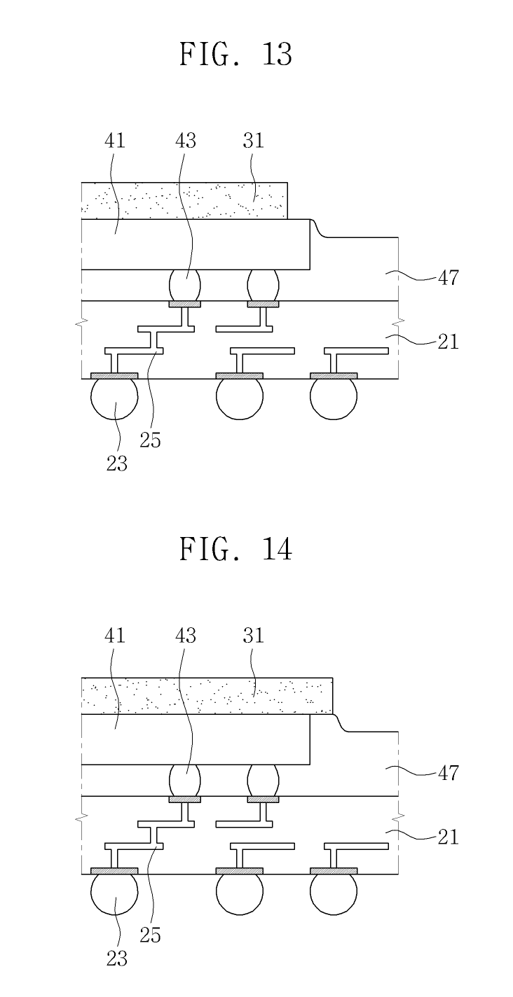

Referring to FIG. 13, the protective layer 31 may have a smaller width than the first semiconductor chip 41. The upper surface of the first encapsulant 47 may be located at the same level as or a lower level than the upper end of the first semiconductor chip 41. The upper surface of the first semiconductor chip 41 may be partially exposed.

Referring to FIG. 14, the protective layer 31 may have a greater width than the first semiconductor chip 41. The upper surface of the first encapsulant 47 may be located at the same level as or a lower level than the upper end of the first semiconductor chip 41. The first encapsulant 47 may be in contact with the bottom of the protective layer 31.

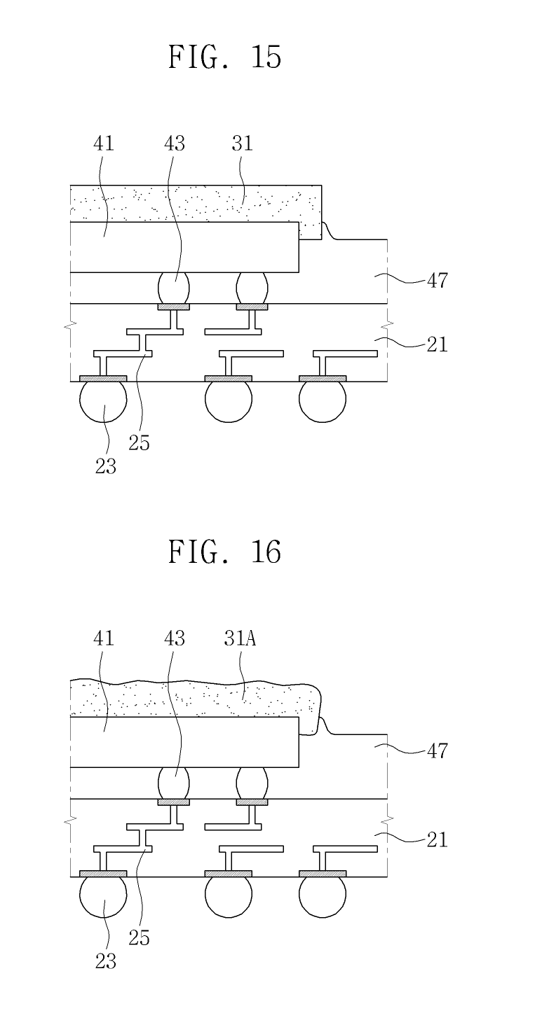

Referring to FIG. 15, the protective layer 31 may have a greater width than the first semiconductor chip 41. The protective layer 31 may partially cover the side surface of the first semiconductor chip 41. The upper surface of the first encapsulant 47 may be located at the same level as or a lower level than the upper end of the first semiconductor chip 41. The protective layer 31 may be interposed between the first semiconductor chip 41 and the first encapsulant 47.

Referring to FIG. 16, the surface of the protective layer 31A may be uneven. The protective layer 31A may fully cover the upper surface of the first semiconductor chip 41 and partially cover the side surface of the first semiconductor chip 41. The upper surface of the first encapsulant 47 may be located at the same level as or a lower level than the upper end of the first semiconductor chip 41. The protective layer 31A may be interposed between the first semiconductor chip 41 and the first encapsulant 47.

Referring to FIG. 17, the protective layer 31 may include a TIM having excellent thermal conductivity. For example, the protective layer 31 may be a tape including a TIM.

Referring to FIG. 18, the protective layer 31 may be formed by curing a liquid or paste type of TIM. For example, the protective layer 31 may be formed using a thermally conductive adhesive, a thermally conductive encapsulant, a thermally conductive compound, or a thermally conductive gel.

Referring to FIG. 19, the protective layer 31 may include a first pattern 32 and a second pattern 33. The second pattern 33 may be a metal having high thermal conductivity. The first pattern 32 may be a thermally conductive adhesive or a tape. According to example embodiments of inventive concepts, the second pattern 33 may include a through-hole, a trench, a groove, or a combination thereof. The first pattern 32 may fully fill the through-hole, trench, or groove of the second pattern 33.

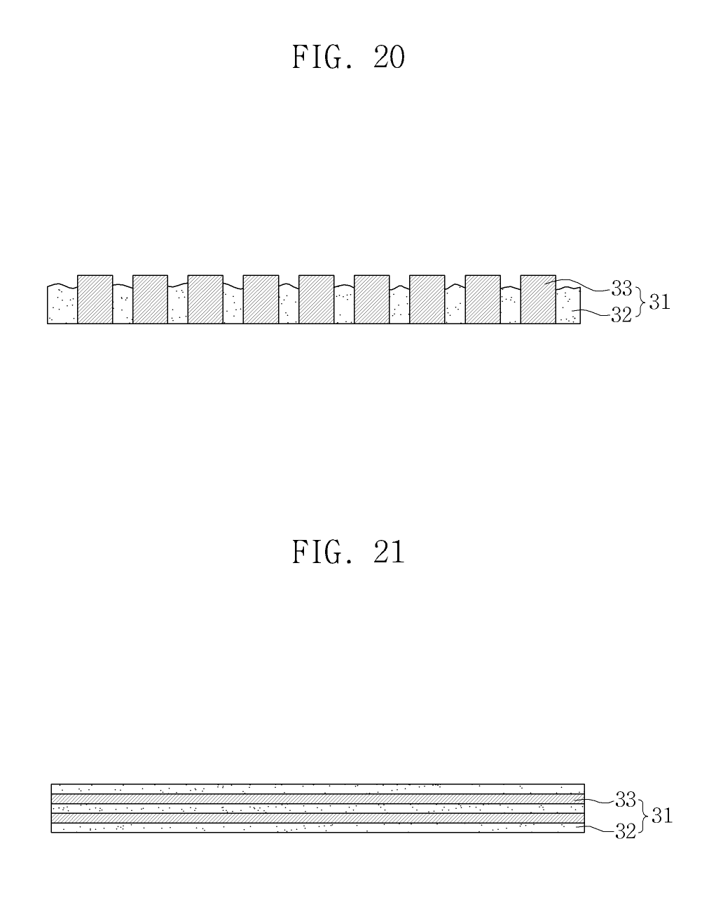

Referring to FIG. 20, the protective layer 31 may include a first pattern 32 and a second pattern 33. A material of the first pattern may be different than a material of the second pattern. The second pattern 33 may be a metal having high thermal conductivity. The first pattern 32 may be formed using a thermally conductive adhesive, a thermally conductive encapsulant, a thermally conductive compound, or a thermally conductive gel. According to example embodiments of inventive concepts, the first pattern 32 may partially fill the through-hole, trench, or groove of the second pattern 33.

Referring to FIG. 21, the protective layer 31 may include first patterns 32 and second patterns 33 which are alternately and repeatedly stacked. The second pattern 33 may be a metal plate having high thermal conductivity. The first pattern 32 may be formed using a tape, a thermally conductive adhesive, a thermally conductive encapsulant, a thermally conductive compound, or a thermally conductive gel.

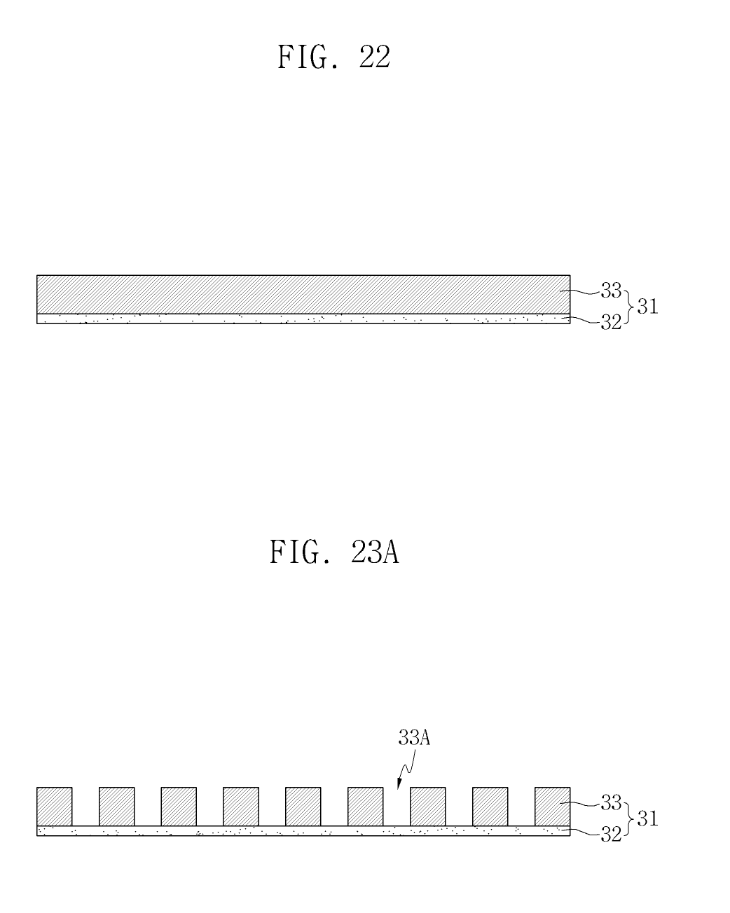

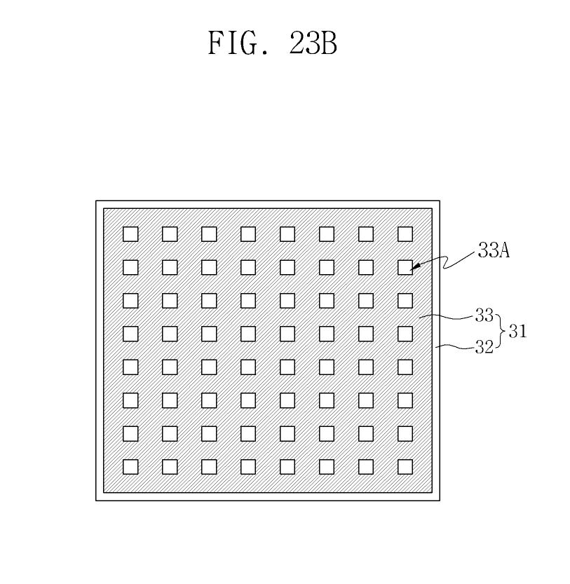

Referring to FIG. 22, the protective layer 31 may include a first pattern 32 and a second pattern 33 which are sequentially stacked. The second pattern 33 may be a metal plate having high thermal conductivity. The first pattern 32 may be formed using a tape, a thermally conductive adhesive, a thermally conductive encapsulant, a thermally conductive compound, or a thermally conductive gel.

Referring to FIGS. 23A and 23B, the protective layer 31 may include a first pattern 32 and a second pattern 33 which are sequentially stacked. The second pattern 33 may be a metal having high thermal conductivity. The first pattern 32 may be a thermally conductive adhesive or a tape. The second pattern 33 may include a plurality of through-holes 33A. The through-holes 33A may be regularly arranged to form a grid.

The second pattern 33 may include a through-hole, a trench, a groove, or a combination thereof which have a variety of shapes and sizes.

As described above, according to example embodiments of inventive concepts, the protective layer 31 may function to protect the first semiconductor chip 41. Even when the first semiconductor chip 41 is formed to have a significantly smaller thickness than in the related art, a semiconductor package having an impact-resistant structure may be implemented. In addition, the protective layer 31 may function to effectively dissipate heat generated from the first semiconductor chip 41.

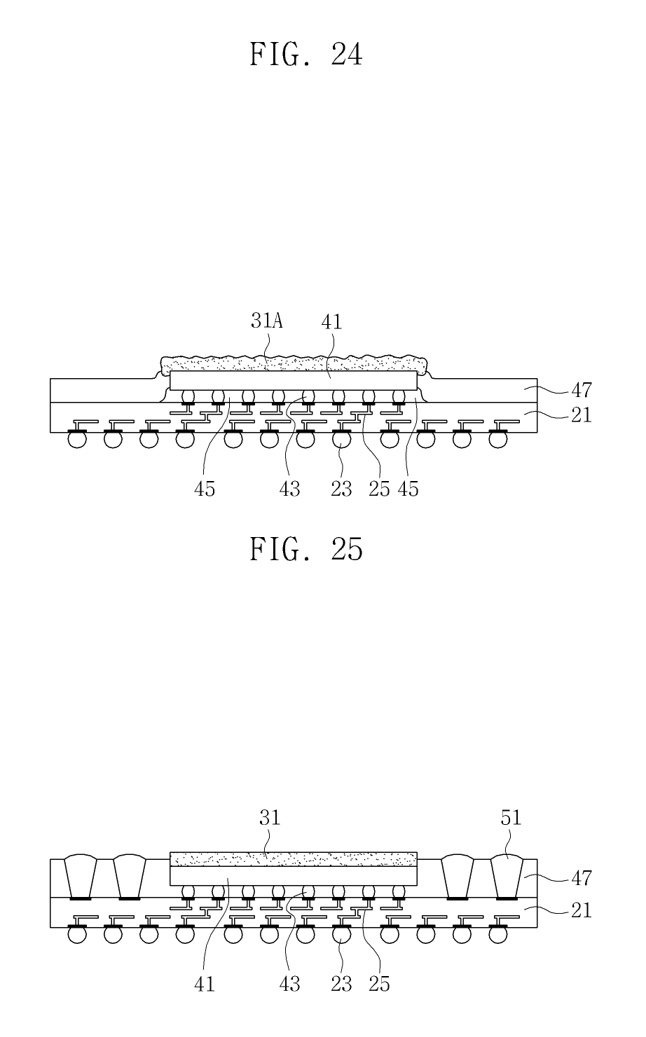

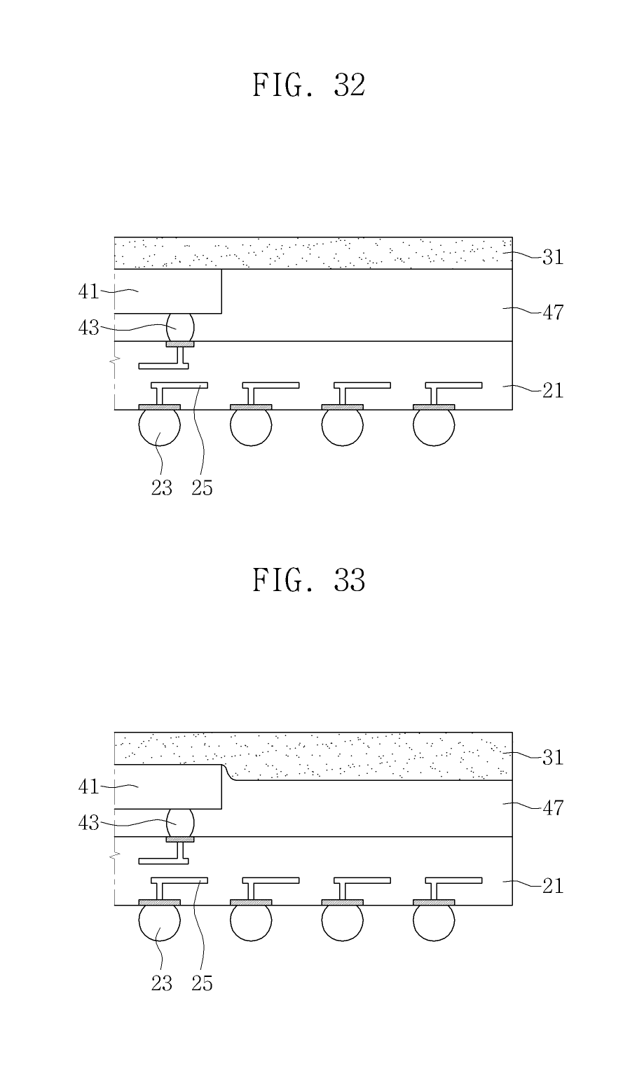

FIGS. 24 to 31 are cross-sectional views for describing semiconductor packages according to example embodiments of the present invention and FIGS. 32 to 35 are enlarged views showing a portion of the semiconductor package shown in FIG. 31 in detail.

Referring to FIG. 24, a filler 45 may be formed between a first substrate 21 and a first semiconductor chip 41. The filler 45 may include an underfill material. The filler 45 may fill a space between the first semiconductor chip 41 and the first substrate 21, and partially cover a side surface of the first semiconductor chip 41. Internal terminals 43 may be in contact with the first semiconductor chip 41 and the first substrate 21 through the filler 45. A first encapsulant 47 may cover the outside of the filler 45. A material of the first encapsulant 47 may be different than a material of the filler 45. An upper surface of the first encapsulant 47 may be located at the same level as or a lower level than an upper end of the first semiconductor chip 41. The first encapsulant 47 may be in contact with side surfaces of the first semiconductor chip 41 and the protective layer 31. A material of the filler 45 may be different than a material of the first encapsulant.

Referring to FIG. 25, through-electrodes 51 connected to the first substrate 21 through the first encapsulant 47 may be formed. The through-electrodes 51 may include a solder ball, a conductive bump, a conductive tab, or a combination thereof.

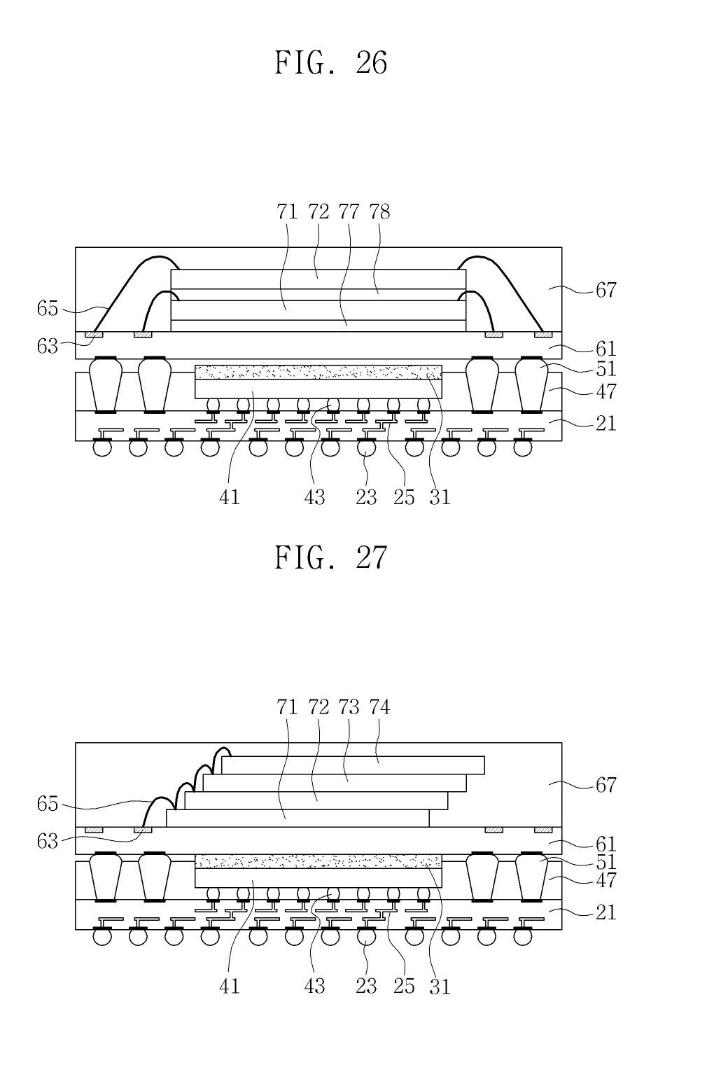

Referring to FIG. 26, a second substrate 61 may be mounted on the first encapsulant 47 and the protective layer 31. The second substrate 61 may be connected to the first substrate 21 via the through-electrodes 51 passing through the first encapsulant 47. Second and third semiconductor chips 71 and 72 may be mounted on the second substrate 61 using adhesive films 77 and 78. The second and third semiconductor chips 71 and 72 may be connected to finger electrodes 63 formed on the second substrate 61 via bonding wires 65. A second encapsulant 67 covering the second and third semiconductor chips 71 and 72 may be formed on the second substrate 61. The protective layer 31 may be configured to be spaced apart from the second substrate 61.

The second substrate 61 may be a PCB that is the same as (or similar to the first substrate 21. The second encapsulant 67 may include a thermosetting resin such as a molding compound, similar to the first encapsulant 48. The second and third semiconductor chips 71 and 72 may have different sizes from the first semiconductor chip 41. The second and third semiconductor chips 71 and 72 may include a non-volatile memory device, a volatile memory device, or a combination thereof. For example, the second and third semiconductor chips 71 and 72 may be DRAMs. The second and third semiconductor chips 71 and 72 may have overhang stack structures.

According to example embodiments of inventive concepts, the second and third semiconductor chips 71 and 72 may include a NAND flash, a magnetic random access memory (MRAM), or a phase-change random access memory (PRAM). However, example embodiments of inventive concepts are not limited thereto.

According to example embodiments of inventive concepts, the first substrate 21, the internal terminals 43, the first semiconductor chip 41, the first encapsulant 47, the protective layer 31, the through-electrodes 51, the second substrate 61, and the second and third semiconductor chips 71 and 72 may configure a package on package (POP).

According to example embodiments of inventive concepts as described above, even when the first semiconductor chip 41 is formed to have a significantly smaller thickness than in the related art, a semiconductor package having an impact-resistant structure may be implemented. A distance between the first substrate 21 and the second substrate 61 may be reduced (and/or minimized). Heights of the through-electrodes 51 may be significantly lowered compared to the related art. Also, pitches of the through-electrodes 51 may be significantly decreased compared to the related art.

Referring to FIG. 27, the protective layer 31 may be in contact with the second substrate 61. The through-electrodes 51 passing through the first encapsulant 47 may be connected to the first and second substrates 21 and 61.

According to example embodiments of inventive concepts, the second substrate 61 may be in contact with the first encapsulant 47 and the protective layer 31.

Second to fifth semiconductor chips 71, 72, 73, and 74 may be sequentially offset aligned and mounted on the second substrate 61. The second to fifth semiconductor chips 71, 72, 73, and 74 may configure a cascade stack. The second to fifth semiconductor chips 71, 72, 73, and 74 may be connected to finger electrodes 63 formed on the second substrate 61 via bonding wires 65. The second to fifth semiconductor chips 71, 72, 73, and 74 may include a non-volatile memory device, a volatile device, or a combination thereof. For example, the second to fifth semiconductor chips 71, 72, 73, and 74 may be a NAND flash.

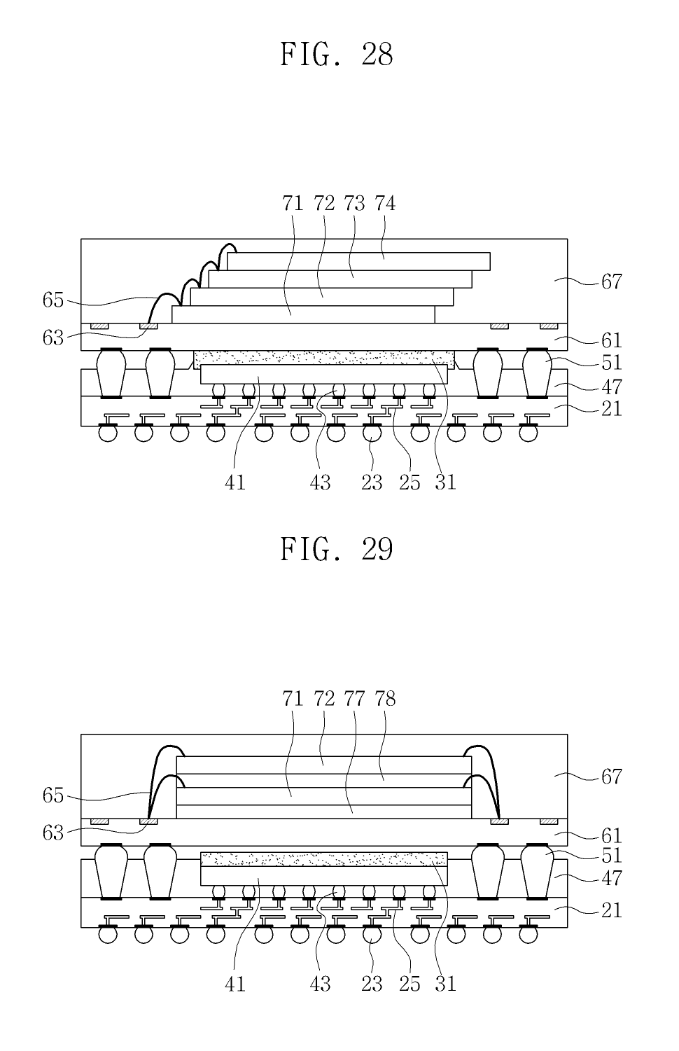

Referring to FIG. 28, the protective layer 31 may be in contact with the second substrate 61. The protective layer 31 may partially cover the side surface of the first semiconductor chip 41. The first encapsulant 47 may be formed at a lower level than the upper end of the first semiconductor chip 41. The through-electrodes 51 passing through the first encapsulant 47 may be connected to the first and second substrates 21 and 61. An empty space may be formed between the second substrate 61 and the first encapsulant 47. Heat generated from the first semiconductor chip 41 may be efficiently dissipated via the protective layer 31 and the empty space.

Referring to FIG. 29, the second and third semiconductor chips 71 and 72 may be mounted on the second substrate 61 using adhesive films 77 and 78. The second and third semiconductor chips 71 and 72 may be connected to a corresponding one of the finger electrodes 63 formed on the second substrate 61 via the bonding wires 65. Connections between the bonding wires 65 and the finger electrodes 63 may have various configurations.

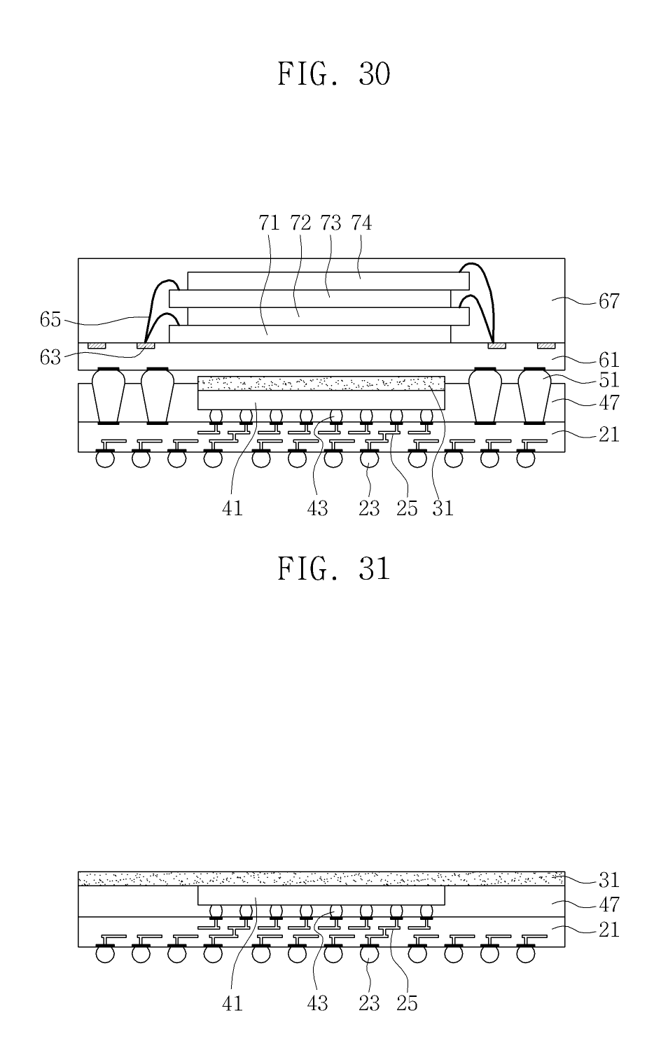

Referring to FIG. 30, the second to fifth semiconductor chips 71, 72, 73, and 74 may be mounted in a zigzag pattern on the second substrate 61. The second to fifth semiconductor chips 71, 72, 73, and 74 may be connected to the finger electrodes 63 formed on the second substrate 61 via the bonding wires 65.

Referring to FIG. 31, the protective layer 31 may be formed to cover the first semiconductor chip 41 and the first encapsulant 47. The protective layer 31 may have a greater width than the first semiconductor chip 41. The protective layer 31 may be directly in contact with the first semiconductor chip 41 and the first encapsulant 47.

Referring to FIG. 32, the protective layer 31 may have the same width as the first encapsulant 47 and the first substrate 21. A side surface of the protective layer 31 may be vertically aligned with a side surface of the first encapsulant 47.

Referring to FIG. 33, the first encapsulant 47 may be formed at a lower level than the upper end of the first semiconductor chip 41. The protective layer 31 may cover the first semiconductor chip 41 and the first encapsulant 47. The thickness of the protective layer 31 may be greater on the first encapsulant 47 than on the first semiconductor chip 41.

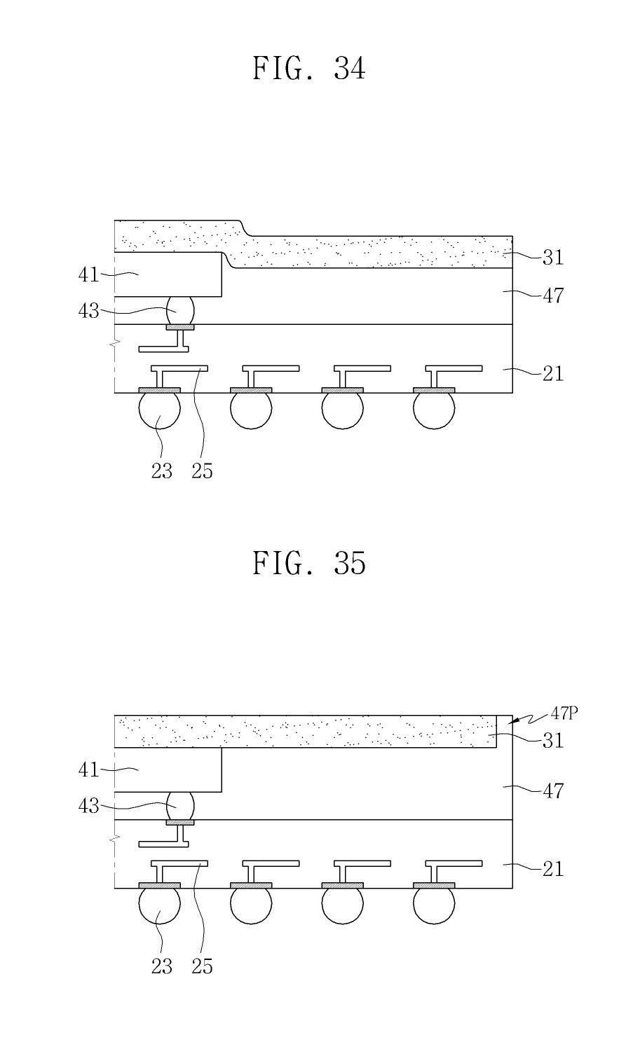

Referring to FIG. 34, the protective layer 31 may cover the upper surfaces of the first semiconductor chip 41 and the first encapsulant 47 to have a uniform thickness.

Referring to FIG. 35, the first encapsulant 47 may include a protrusion 47P covering the side surface of the protective layer 31. The upper surfaces of the protrusion 47P and the protective layer 31 may be formed at substantially the same level. The protective layer 31 may have a smaller width than the first encapsulant 47 and the first substrate 21.

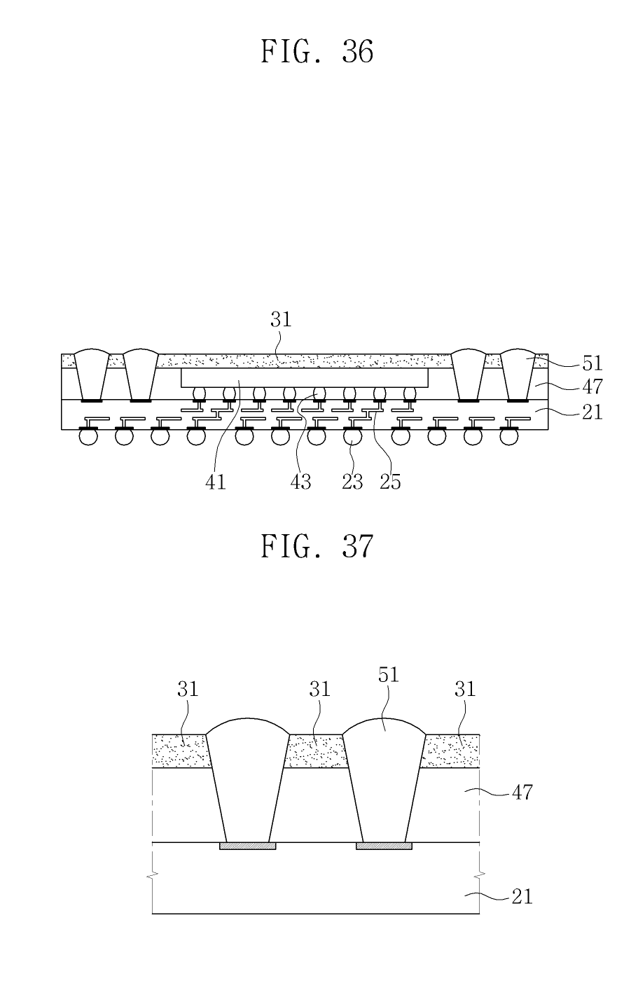

FIG. 36 is a cross-sectional view for describing a semiconductor package according to example embodiments of inventive concepts, and FIGS. 37 to 39 are enlarged views for describing a portion of the semiconductor package shown in FIG. 36 in detail.

Referring to FIG. 36, through-electrodes 51 connected to the first substrate 21 through the protective layer 31 and the first encapsulant 47 may be formed. The through electrodes 51 may include a solder ball, a conductive bump, a conductive tab, or a combination thereof.

Referring to FIG. 37, the through-electrodes 51 may be in contact with the side surfaces of the protective layer 31 and the first encapsulant 47.

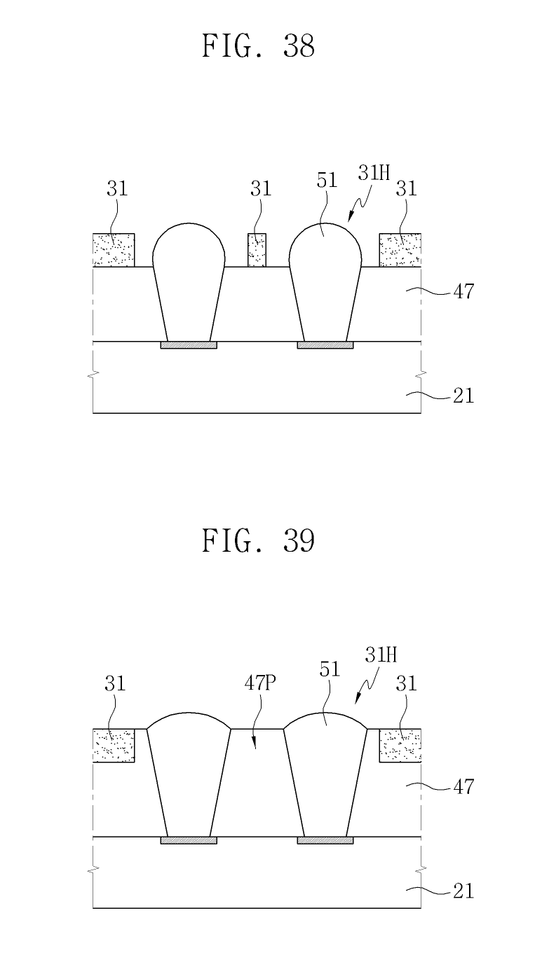

Referring to FIG. 38, the protective layer 31 may include a plurality of through-holes 31H. The through-electrodes 51 connected to the first substrate 21 through the first encapsulant 47 may be formed in the through-holes 31H. The first encapsulant 47 may be partially exposed in the through-holes 31H.

Referring to FIG. 39, the protective layer 31 may include the through-hole 31H. The first encapsulant 47 may include the protrusion 47P filling the through-hole 31H. Upper surfaces of the protrusion 47P and the protective layer 31 may be formed at substantially the same level. The through-electrodes 51 connected to the first substrate 21 through the protrusion 47P may be formed.

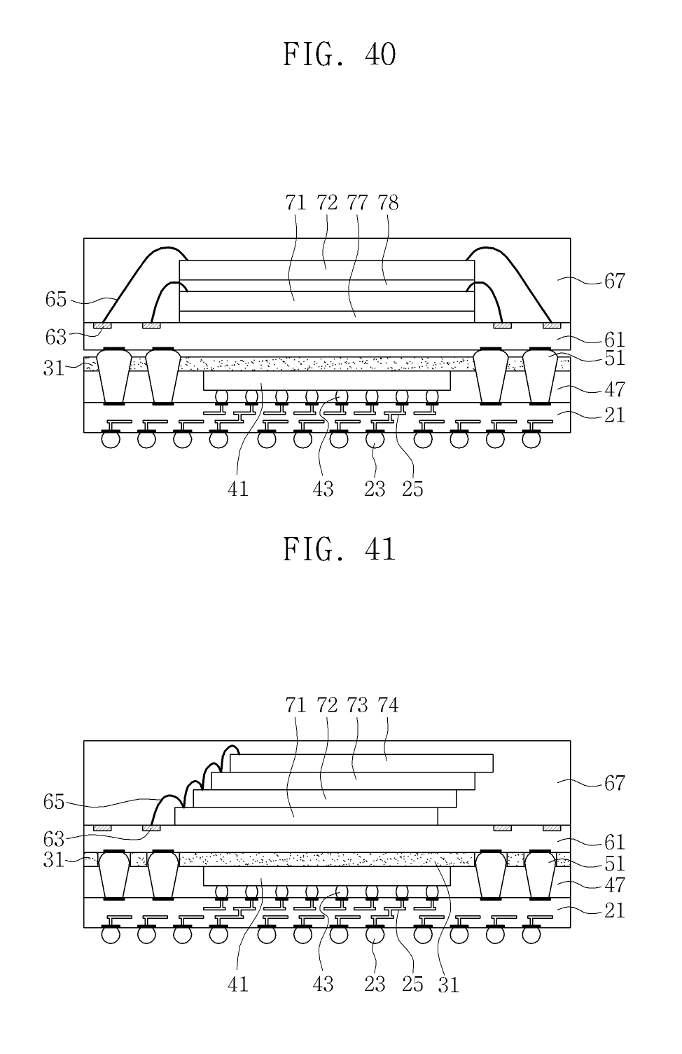

FIGS. 40 to 43 are cross-sectional views for describing semiconductor packages according to example embodiments of inventive concepts.

Referring to FIG. 40, a second substrate 61 may be mounted on the protective layer 31. The second substrate 61 may be connected to the first substrate 21 via the through-electrodes 51 passing through the protective layer 31 and the first encapsulant 47. Second and third semiconductor chips 71 and 72 may be mounted on the second substrate 61 using adhesive films 77 and 78. The second and third semiconductor chips 71 and 72 may be connected to finger electrodes 63 formed on the second substrate 61 via bonding wires 65. A second encapsulant 67 covering the second and third semiconductor chips 71 and 72 may be formed on the second substrate 61. The protective layer 31 may be formed to be spaced apart from the second substrate 61. The protective layer 31 may function to protect the first semiconductor chip 41 and the first encapsulant 47, and to dissipate heat generated from the first semiconductor chip 41.

Referring to FIG. 41, the second substrate 61 may be in contact with the protective layer 31. The second substrate 61 may be connected to the first substrate 21 via the through-electrodes 51 passing through the protective layer 31 and the first encapsulant 47. Second to fifth semiconductor chips 71, 72, 73, and 74 may be sequentially offset aligned and mounted on the second substrate 61.

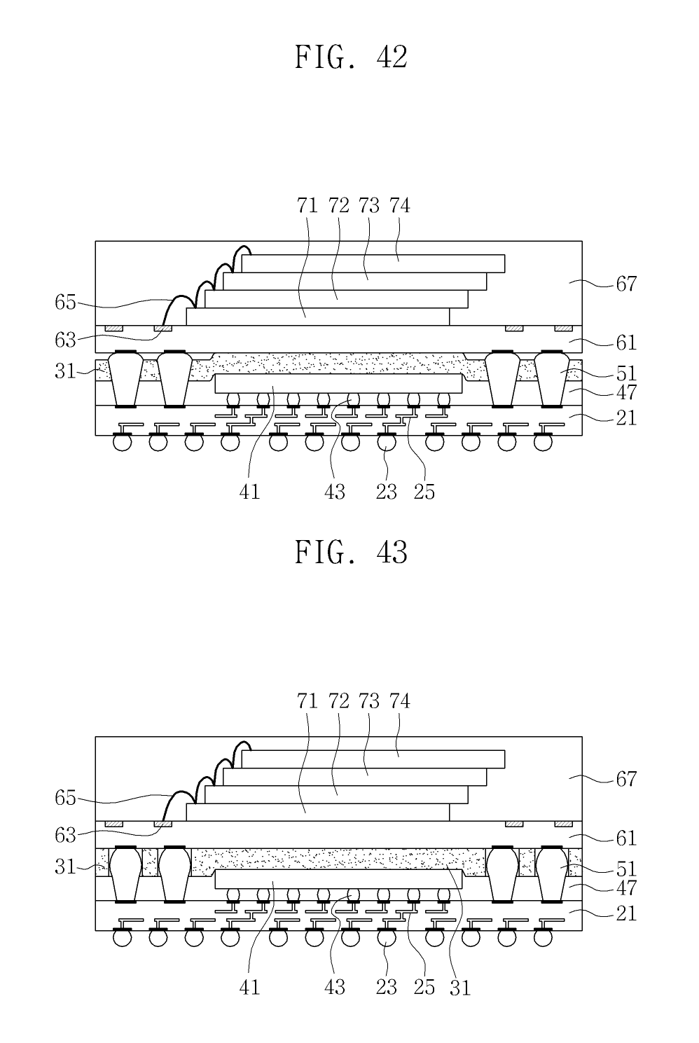

Referring to FIG. 42, the first encapsulant 47 may be formed at a lower level than the upper end of the first semiconductor chip 41. The protective layer 31 may cover the upper surfaces of the first semiconductor chip 41 and the first encapsulant 47 to have a uniform thickness. The second substrate 61 may be partially in contact with the protective layer 31. The second substrate 61 may be connected to the first substrate 21 via the through-electrodes 51 passing through the protective layer 31 and the first encapsulant 47.

Referring to FIG. 43, the first encapsulant 47 may be formed at a lower level than the upper end of the first semiconductor chip 41. The protective layer 31 may cover the upper surfaces of the first semiconductor chip 41 and the first encapsulant 47. The thickness of the protective layer 31 may be greater on the first encapsulant 47 than on the first semiconductor chip 41. The second substrate 61 may be in contact with the protective layer 31.

Methods of forming semiconductor packages according to example embodiments of inventive concepts will be described with reference again to FIGS. 1 to 43.

Referring again to FIG. 1, a first semiconductor chip 41 may be mounted on a first substrate 21 using internal terminals 43. A protective layer 31 may be mounted on the first semiconductor chip 41. A first encapsulant 47 may be formed on the first substrate 21. The first encapsulant 47 may be in contact with side surfaces of the first semiconductor chip 41 and the protective layer 31. The first substrate 21 may include a plurality of internal wirings 25. External terminals 23 may be formed in one surface of the first substrate 21. The external terminals 23 may be omitted.

The protective layer 31 may be mounted on the first semiconductor chip 41 before forming the internal terminals 43. The protective layer 31 may be mounted on the first semiconductor chip 41 during formation of the first encapsulant 47.

Referring to FIG. 2, upper surfaces of the first encapsulant 47 and the protective layer 31 may be formed at substantially the same level. The protective layer 31 may have the same width as the first semiconductor chip 41.

Referring to FIG. 3, the protective layer 31 may have a smaller width than the first semiconductor chip 41.

Referring to FIG. 4, the protective layer 31 may have a greater width than the first semiconductor chip 41.

Referring to FIG. 5, the protective layer 31 may have a greater width than the first semiconductor chip 41. The protective layer 31 may partially cover the side surface of the first semiconductor chip 41.

Referring to FIG. 6, the surface of the protective layer 31 may be uneven. The protective layer 31 may fully cover the upper surface of the first semiconductor chip 41 and partially cover the side surface of the first semiconductor chip 41. The protective layer 31 may be formed by curing a liquid or paste type of TIM.

Referring to FIG. 7, the upper surface of the first encapsulant 47 may be located at a higher level than the first semiconductor chip 41 and at a lower level than the upper end of the protective layer 31. The protective layer 31 may have the same width as the first semiconductor chip 41.

Referring to FIG. 8, the protective layer 31 may have a smaller width than the first semiconductor chip 41.

Referring to FIG. 9, the protective layer 31 may have a greater width than the first semiconductor chip 41.

Referring to FIG. 10, the protective layer 31 may have a greater width than the first semiconductor chip 41. The protective layer 31 may partially cover the side surface of the first semiconductor chip 41.

Referring to FIG. 11, the surface of the protective layer 31 may be uneven. The upper surface of the first encapsulant 47 may be located at a higher level than the first semiconductor chip 41 and at a lower level than the upper end of the protective layer 31.

Referring to FIG. 12, the first encapsulant 47 may be located at a lower level than the protective layer 31. The protective layer 31 may have the same width as the first semiconductor chip 41.

Referring to FIG. 13, the protective layer 31 may have a smaller width than the first semiconductor chip 41.

Referring to FIG. 14, the protective layer 31 may have a greater width than the first semiconductor chip 41. The first encapsulant 47 may be in contact with the bottom of the protective layer 31.

Referring to FIG. 15, the protective layer 31 may have a greater width than the first semiconductor chip 41. The protective layer 31 may partially cover the side surface of the first semiconductor chip 41. The upper surface of the first encapsulant 47 may be located at the same level as or a lower level than the upper end of the first semiconductor chip 41. The protective layer 31 may extend between the first semiconductor chip 41 and the first encapsulant 47.

Referring to FIG. 16, the surface of the protective layer 31 may be uneven. The protective layer 31 may extend between the first semiconductor chip 41 and the first encapsulant 47.

Referring to FIG. 17, the protective layer 31 may include a TIM having excellent thermal conductivity. For example, the protective layer 31 may be formed using a tape including a TIM.

Referring to FIG. 18, the protective layer 31A may be formed by curing a liquid or paste type of TIM. For example, the protective layer 31A may be formed using a thermally conductive adhesive, a thermally conductive encapsulant, a thermally conductive compound, or a thermally conductive gel.

Referring to FIG. 19, the protective layer 31 may include a first pattern 32 and a second pattern 33. The second pattern 33 may be a metal having excellent thermal conductivity. The first pattern 32 may be a thermally conductive adhesive or a tape.

Referring to FIG. 20, the protective layer 31 may include a first pattern 32 and the second pattern 33. The first pattern 32 may be formed using a thermally conductive adhesive, a thermally conductive encapsulant, a thermally conductive compound, or a thermally conductive gel.

Referring to FIG. 21, the protective layer 31 may include first patterns 32 and second patterns 33 which are alternately and repeatedly stacked.

Referring to FIG. 22, the protective layer 31 may include a first pattern 32 and a second pattern 33 which are sequentially stacked.

Referring to FIGS. 23A and 23B, the protective layer 31 may include a first pattern 32 and a second pattern 33 which are sequentially stacked. The second pattern 33 may include a plurality of through-holes 33A.

Referring to FIG. 24, a filler 45 may be formed between the first substrate 21 and the first semiconductor chip 41. The filler 45 may include an underfill material. Internal terminals 43 may be in contact with the first semiconductor chip 41 and the first substrate 21 through the filler 45. The first encapsulant 47 may cover the outside of the filler 45.

Referring to FIG. 25, through-electrodes 51 connected to the first substrate 21 through the first encapsulant 47 may be formed.

Referring to FIG. 26, a second substrate 61 may be mounted on the first encapsulant 47 and the protective layer 31. The second substrate 61 may be connected to the first substrate 21 via the through-electrodes 51 passing through the first encapsulant 47. Second and third semiconductor chips 71 and 72 may be mounted on the second substrate 61 using adhesive films 77 and 78. According to example embodiments of inventive concepts, the first substrate 21, the internal terminals 43, the first semiconductor chip 41, the first encapsulant 47, the protective layer 31, the through-electrodes 51, the second substrate 61, and the second and third semiconductor chips 71 and 72 may configure a POP.

Referring to FIG. 27, the protective layer 31 may be in contact with the second substrate 61.

Referring to FIG. 28, the protective layer 31 may partially cover the side surface of the first semiconductor chip 41. The first encapsulant 47 may be formed at a lower level than the upper end of the first semiconductor chip 41.

Referring to FIG. 29, connections between bonding wires 65 and finger electrodes 63 may have various configurations.

Referring to FIG. 30, the second to fifth semiconductor chips 71, 72, 73, and 74 may be mounted in a zigzag pattern on the second substrate 61.

Referring to FIG. 31, the protective layer 31 may be formed to cover the first semiconductor chip 41 and the first encapsulant 47. The protective layer 31 may be directly in contact with the first semiconductor chip 41 and the first encapsulant 47.

Referring to FIG. 32, the protective layer 31 may have the same width as the first encapsulant 47 and the first substrate 21.

Referring to FIG. 33, the first encapsulant 47 may be formed at a lower level than the upper end of the first semiconductor chip 41. The protective layer 31 may cover the first semiconductor chip 41 and the first encapsulant 47. The thickness of the protective layer 31 may be greater on the first encapsulant 47 than on the first semiconductor chip 41.

Referring to FIG. 34, the protective layer 31 may cover the upper surfaces of the first semiconductor chip 41 and the first encapsulant 47 to have a uniform thickness.

Referring to FIG. 35, the first encapsulant 47 may include a protrusion 47P covering the side surface of the protective layer 31.

Referring to FIG. 36, through-electrodes 51 connected to the first substrate 21 through the protective layer 31 and the first encapsulant 47 may be formed.

Referring to FIG. 37, the through-electrodes 51 may be in contact with the side surfaces of the protective layer 31 and the first encapsulant 47.

Referring to FIG. 38, the protective layer 31 may include a plurality of through-holes 31H. The through-electrodes 51 connected to the first substrate 21 through the first encapsulant 47 may be formed in the through-holes 31H.

Referring to FIG. 39, the protective layer 31 may include the through-hole 31H. The first encapsulant 47 may include the protrusion 47P filling the through-hole 31H. The through-electrodes 51 connected to the first substrate 21 through the protrusion 47P may be formed.

Referring to FIG. 40, a second substrate 61 may be mounted on the protective layer 31. Second and third semiconductor chips 71 and 72 may be mounted on the second substrate 61 using adhesive films 77 and 78. A second encapsulant 67 covering the second and third semiconductor chips 71 and 72 may be formed on the second substrate 61

Referring to FIG. 41, the second substrate 61 may be in contact with the protective layer 31.

Referring to FIG. 42, the first encapsulant 47 may be formed at a lower level than the upper end of the first semiconductor chip 41. The protective layer 31 may cover the upper surfaces of the first semiconductor chip 41 and the first encapsulant 47 to have a uniform thickness. The second substrate 61 may be partially in contact with the protective layer 31.

Referring to FIG. 43, the first encapsulant 47 may be formed at a lower level than the upper end of the first semiconductor chip 41. The protective layer 31 may cover the upper surfaces of the first semiconductor chip 41 and the first encapsulant 47. The thickness of the protective layer 31 may be greater on the first encapsulant 47 than on the first semiconductor chip 41. The second substrate 61 may be in contact with the protective layer 31.

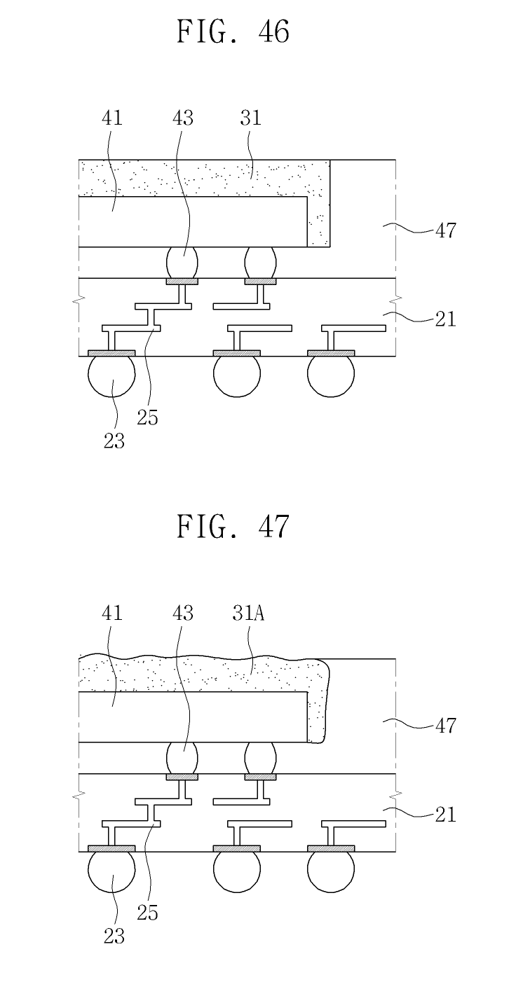

Referring to FIG. 46, in example embodiments, the protective layer 31 may contact an entire sidewall of the first semiconductor chip 41.

Referring to FIG. 47, in example embodiments, the protective layer 31A may have an uneven shape that covers an entire sidewall of the semiconductor chip 41.

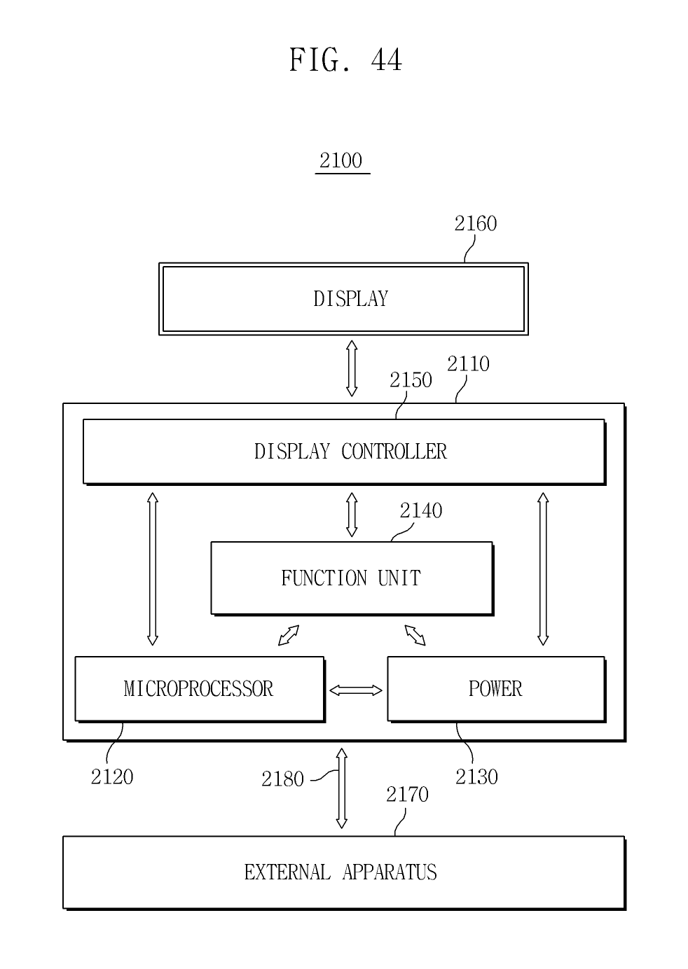

FIG. 44 is a system block diagram for describing an electronic apparatus according to example embodiments of inventive concepts.

Referring to FIG. 44, the semiconductor package described with reference to FIGS. 1 to 43 may be applied to an electronic system 2100. The electronic system 2100 may include a body 2110, a microprocessor unit 2120, a power unit 2130, a function unit 2140, and a display controller unit 2150. The body 2110 may be a motherboard formed of a PCB. The microprocessor unit 2120, the power unit 2130, the function unit 2140, and the display controller unit 2150 may be mounted on the body 2110. A display unit 2160 may be installed inside or outside of the body 2110. For example, the display unit 2160 may be installed on the surface of the body 2110 to display an image processed by display controller unit 2150.

The power unit 2130 may function to receive a constant voltage from an external battery (not shown), divide the voltage into required levels, and supply those voltages to the microprocessor unit 2120, the function unit 2140, and the display controller unit 2150. The microprocessor unit 2120 may receive the voltage from the power unit 2130 to control the function unit 2140 and the display unit 2160. The function unit 2140 may perform functions of various electronic systems 2100. For example, if the electronic system 2100 is a cellular phone, the function unit 2140 may have several components which can perform functions of a cellular phone such as dialing, video output to the display unit 2160 through communication with the external apparatus 2170, and sound output to a speaker, and if a camera is installed, the function unit 2140 may function as a camera image processor.

According to example embodiments of inventive concepts, when the electronic system 2100 is connected to a memory card, etc. in order to expand capacity, the function unit 2140 may be a memory card controller. The function unit 2140 may exchange signals with the external apparatus 2170 through a wired or wireless communication unit 2180. Further, when the electronic system 2100 includes a universal serial bus (USB) in order to expand functionality, the function unit 2140 may function as an interface controller. In addition, the function unit 2140 may include a mass storage device.

The semiconductor package described with reference to FIG. 1 to FIG. 43 can be applied to the function unit 2140 or the microprocessor unit 2120. For example, the function unit 2140 may include the protective layer 31. Due to the configuration of the protective layer 31, the function unit 2120 is useful in being formed to be light, thin, short, and small, and shows better heat dissipation characteristics than in the related art.

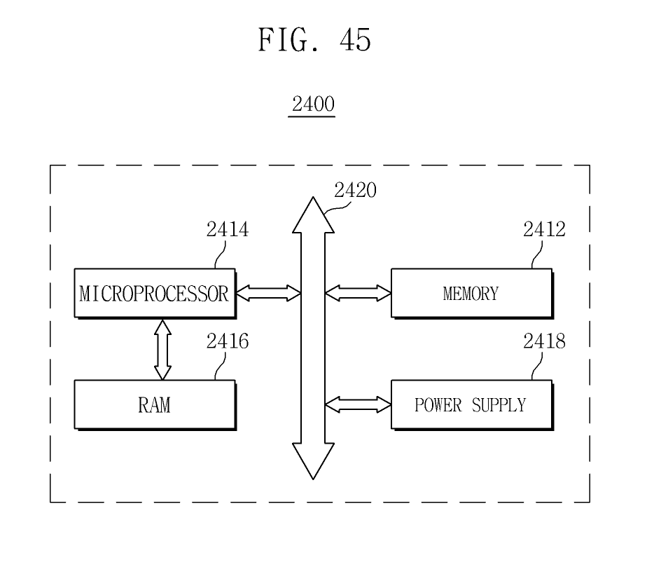

FIG. 45 is a block diagram schematically describing another electronic system 2400 which includes at least one of the semiconductor packages according to example embodiments of inventive concepts.

Referring to FIG. 45, the electronic system 2400 may include at least one of the semiconductor packages according to example embodiments of inventive concepts. The electronic system 2400 may be used to fabricate a mobile apparatus or a computer. For example, the electronic system 2400 may include a memory system 2412, a microprocessor 2414, a RAM 2416, and a power supply device 2418. The microprocessor 2414 may program and control the electronic system 2400. The RAM 2416 may be used as an operation memory of the microprocessor 2414. The microprocessor 2414, the RAM, and/or other components can be assembled in a single package. The memory system 2142 may store codes for operating the microprocessor 2414, data processed by the microprocessor 2414, or external input data. The memory system 2412 may include a controller and a memory.

A semiconductor package similar to that described with reference to FIG. 1 to FIG. 43 can be applied to the microprocessor 2414, the RAM 2416, or the memory system 2412. For example, the microprocessor 2414 may include the protective layer 31. Due to the configuration of the protective layer 31, the microprocessor 2414 is useful in being formed to be light, thin, short, and small, and shows better heat dissipation characteristics than in the related art.

According to example embodiments of inventive concepts, a flip-chip package having the first substrate, the first semiconductor chip, the first encapsulant, and the protective layer can be provided. The protective layer can function to protect the first semiconductor chip and dissipate heat generated from the first semiconductor chip. Even when the first semiconductor chip is formed to have a significantly smaller thickness than in the related art, a semiconductor package having an impact-resistant structure can be implemented. In addition, second and third substrates can be mounted on the protective layer. Through-electrodes can be formed between the first substrate and the second substrate. The pitch of the through-electrodes can be significantly decreased compared to the related art, by reducing (and/or minimizing) a distance between the first and second substrates. A semiconductor package which is useful in being formed to be light, thin, short, and small, and shows excellent electrical characteristics can be realized.

While some example embodiments have been particularly shown and described, it will be understood by one of ordinary skill in the art that variations in form and detail may be made therein without departing from the spirit and scope of the claims.

In the claims, means-plus-function clauses are intended to cover the structures described herein as performing the recited function, and not only structural equivalents but also equivalent structures.

What is claimed is:

1. A semiconductor package, comprising:
a first semiconductor chip on a first substrate;
a protective layer directly on the first semiconductor chip; and
an encapsulant covering an upper surface of the first substrate, wherein
the encapsulant contacts side surfaces of the first semiconductor chip and the protective layer, and
an upper surface of the encapsulant is at a higher level than the first semiconductor chip.

2. The semiconductor package according to claim 1, further comprising:
a second substrate on the protective layer and the encapsulant;
a second semiconductor chip on the second substrate; and
a through-electrode connected through the encapsulant to the first and second substrates.

3. The semiconductor package according to claim 2, wherein the protective layer contacts the second substrate.

4. The semiconductor package according to claim 1, wherein the upper surface of the encapsulant is at an equal level to an upper surface of the protective layer.

5. The semiconductor package according to claim 1, wherein a width of the protective layer is greater than a width of the first semiconductor chip.

6. The semiconductor package according to claim 1, wherein the protective layer is in contact with an upper surface of the first semiconductor chip and the side surfaces of the first semiconductor chip.

7. The semiconductor package according to claim 1, wherein the protective layer includes a thermal interface material (TIM).

8. A semiconductor package, comprising:
a first semiconductor chip on a first substrate;
an encapsulant covering an upper surface of the first substrate,
the encapsulant contacting a side surface of the first semiconductor chip; and
a protective layer directly contacting an upper surface of the first semiconductor chip and an upper surface of the encapsulant, wherein
the protective layer includes a thermal interface material (TIM),
a width of the protective layer is greater than a width of the first semiconductor chip, and
an upper surface of the encapsulant is at a lower level than an upper end of the first semiconductor chip.

9. The semiconductor package according to claim 8, further comprising:
a second substrate on the protective layer;
a second semiconductor chip on the second substrate; and
a through-electrode connected through the protective layer and the encapsulant to the first and second substrates.

10. The semiconductor package according to claim 9, wherein
the encapsulant includes a protrusion, and
the protrusion of the encapsulant contacts a side surface of the protective layer.

11. The semiconductor package according to claim 10, wherein upper ends of the protrusion are at an equal level with upper ends of the protective layer.

12. The semiconductor package according to claim 8, wherein a thickness of the protective layer between the encapsulant and the second substrate is greater than a thickness of the protective layer between the first semiconductor chip and the second substrate.

13. A semiconductor package, comprising:
an encapsulant on a first substrate;
a first semiconductor chip on the encapsulant,
the encapsulant contacting a sidewall of the first semiconductor chip; and
a protective layer directly on the first semiconductor chip,
the protective layer contacting at least one of an upper surface of the encapsulant, the sidewall of the first semiconductor chip, and a sidewall of the encapsulant.

14. The semiconductor package of claim 13, wherein
the protective layer contacts a first part of the sidewall of the first semiconductor chip,
the encapsulant contacts a second part of the sidewall of the first semiconductor chip, and
the protective layer extends between the encapsulant and the first part of the sidewall of the first semiconductor chip.

15. The semiconductor package of claim 13, wherein
a width of the protective layer is different than a width of the first semiconductor chip, and
a portion of the encapsulant extends between the sidewall of the first semiconductor chip and the protective layer.

16. The semiconductor package of claim 13, further comprising:
second substrate on the protective layer; and
a second semiconductor chip on the second substrate.

17. The semiconductor package of claim 13, wherein the protective layer includes:
a first pattern containing a thermally-conductive adhesive, and
a second pattern containing a different material than the first pattern.
